(19) United States
(12) Patent Application Publication
(10) Pub. No.: US 2026/0006881 A1
(43) Pub. Date: Jan. 1, 2026

(54) WRAP AROUND CONTACT WITH SELF-ALIGNED GATE ISOLATION

(71) Applicant: International Business Machines Corporation, Armonk, NY (US)

(72) Inventors: Tsung-Sheng Kang, Ballston Lake, NY (US); Alexander Reznicek, Troy, NY (US); Ruilong Xie, Niskayuna, NY (US); Sagarika Mukesh, ALBANY, NY (US)

(21) Appl. No.: 18/756,004

(22) Filed: Jun. 27, 2024

(51) Int. Cl. H01L 29/417; H01L 23/528; H01L 27/088; H01L 29/06; H01L 29/423; H01L 29/66; H01L 29/775; H01L 29/786

(52) U.S. Cl. CPC H10D 64/254; H01L 23/5286; H10D 30/014; H10D 30/43; H10D 30/6735; H10D 30/6757; H10D 62/121; H10D 84/83

(57) ABSTRACT

Semiconductor devices with self-aligned gate isolation and wrap around source/drain contacts are provided. In one aspect, a semiconductor device includes: at least a first FET (FET1) and a second FET (FET2), adjacent to one another on a wafer; a dielectric bar between gates of the FET1 and the FET2, and between source/drain regions of the FET1 and the FET2; and wrap around source/drain contacts that at least partially surround the source/drain regions of the FET1 and the FET2. A shallow trench isolation (STI) region can be present between the FET1 and the FET2 and the dielectric bar can be centered over, and directly contact the STI region. Portions of the dielectric bar between the gates and between the source/drain regions can have a height H1 and H2, respectively, where H1>H2. A method of fabricating the present semiconductor device is also provided.

### BACKGROUND

The present invention generally relates to semiconductor devices such as field-effect transistors (FETs), and, more particularly, to semiconductor devices with self-aligned gate isolation and wrap around source/drain contacts, and techniques for fabrication thereof.

Integrated circuit process flows typically involve first forming a sacrificial gate, and then performing a gate cut between adjacent devices. After these steps are performed, replacement metal gates are formed. Doing so, however, can require complex and costly processes such as extreme ultraviolet (EUV) lithography for the gate cut that often need to be performed within tight tolerances and very high aspect ratio. This approach becomes even more challenging when device scaling is a factor.

### BRIEF SUMMARY

Principles of the invention provide semiconductor devices with self-aligned gate isolation and wrap around source/drain contacts. In one aspect, a semiconductor device is provided. The semiconductor device includes: at least a first field-effect transistor (FET1) and a second FET (FET2), adjacent to one another on a wafer; a dielectric bar between gates of the FET1 and the FET2, and between source/drain regions of the FET1 and the FET2; and wrap around source/drain contacts that at least partially surround the source/drain regions of the FET1 and the FET2.

In another aspect, another semiconductor device is provided. The semiconductor device includes: at least a first FET (FET1) and a second FET (FET2), adjacent to one another on a wafer; a shallow trench isolation (STI) region between the FET1 and the FET2; a dielectric bar between gates of the FET1 and the FET2, and between source/drain regions of the FET1 and the FET2, where the dielectric bar is centered over, and directly contacts the STI region, where a portion of the dielectric bar between the gates of the FET1 and the FET2 has a height H1, where another portion of the dielectric bar between the source/drain regions of the FET1 and the FET2 has a height H2, and where H1>H2; and wrap around source/drain contacts that at least partially surround the source/drain regions of the FET1 and the FET2.

In yet another aspect, a method of fabricating a semiconductor device is provided. The method includes: forming at least a first device stack corresponding to a first FET (FET1) and a second device stack corresponding to a second FET (FET2), adjacent to one another on a wafer, where the first device stack and the second device stack each includes sacrificial layers and active layers; forming a dielectric bar between the first device stack and the second device stack; depositing a sacrificial placeholder in a source/drain area adjacent to the first device stack and the second device stack; forming source/drain regions of the FET1 and the FET2 in the sacrificial placeholder; removing the sacrificial layers from the first device stack and the second device stack; forming gates of the FET1 and the FET2 that surround a portion of each of the active layers in a gate-all-around configuration; and replacing the sacrificial placeholder with wrap around source/drain contacts that at least partially surround the source/drain regions of the FET1 and the FET2, where the dielectric bar is present between the gates of the FET1 and the FET2, and between the source/drain regions of the FET1 and the FET2.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-53 show exemplary steps in the fabrication of an exemplary semiconductor device, according to aspects of the invention, where FIG. 1 is a top-down view and the remaining figures are the X, Y1 and Y2 cross-sectional views (as respectively labeled) indicated in FIG. 1; and

FIGS. 54-59 are X, Y1 and Y2 cross-sectional views (as respectively labeled), which follow from FIGS. 21-23, that show exemplary steps in the fabrication of an exemplary semiconductor device, according to other aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, a semiconductor device (e.g., semiconductor device 5120, 5720, etc.) is provided. The semiconductor device (e.g., semiconductor device 5120, 5720, etc.) includes: at least a first field-effect transistor (e.g., FET1) and a second FET (e.g., FET2), adjacent to one another on a wafer (e.g., wafer 201). A dielectric bar (e.g., one of dielectric bars 502) is present between gates (e.g., replacement metal gates 3002, 3002′, etc.) of the FET1 and the FET2, and between source/drain regions (e.g., source/drain regions 2702, 2702′, etc.) of the FET1 and the FET2. Wrap around source/drain contacts (e.g., wrap around source/drain contacts 3902, 3902′, etc.) at least partially surround the source/drain regions (e.g., source/drain regions 2702, 2702′, etc.) of the FET1 and the FET2.

In another aspect, another semiconductor device (e.g., semiconductor device 5120, 5720, etc.) is provided. The semiconductor device (e.g., semiconductor device 5120, 5720, etc.) includes: at least a first FET (FET1) and a second FET (FET2), adjacent to one another on a wafer (e.g., wafer 201). A shallow trench isolation (STI) region (e.g., one of STI regions 302) is present between the FET1 and the FET2. A dielectric bar (e.g., one of dielectric bars 502) is present between gates (e.g., replacement metal gates 3002, 3002′, etc.) of the FET1 and the FET2, and between source/drain regions (e.g., source/drain regions 2702, 2702′, etc.) of the FET1 and the FET2. The dielectric bar is centered over, and directly contacts the STI region. A portion of the dielectric bar between the gates (e.g., replacement metal gates 3002, 3002′, etc.) of the FET1 and the FET2 has a height H1, another portion of the dielectric bar between the source/drain regions (e.g., source/drain regions 2702, 2702′, etc.) of the FET1 and the FET2 has a height H2, and where H1>H2. Wrap around source/drain contacts (e.g., wrap around source/drain contacts 3902, 3902′, etc.) at least partially surround the source/drain regions (e.g., source/drain regions 2702, 2702′, etc.) of the FET1 and the FET2.

In yet another aspect, a method of fabricating a semiconductor device (e.g., semiconductor device 5120, 5720, etc.) is provided. According to the method, at least a first device stack (e.g., one of device stacks 200a,b,c, etc.) corresponding to a first FET (FET1) and a second device stack (e.g., another of device stacks 200a,b,c, etc.) corresponding to a second FET (FET2) are formed, adjacent to one another on a wafer (e.g., wafer 201). The first device stack and the second device stack each includes sacrificial layers (e.g., sacrificial layers 204a,b,c,d, etc./sacrificial layer 206) and active layers (e.g., active layers 208a,b,c, etc.). A dielectric bar (e.g., one of dielectric bars 502) is formed between the first device stack and the second device stack. A sacrificial placeholder (e.g., sacrificial placeholder 2102) is deposited in a source/drain area adjacent to the first device stack and the second device stack. Source/drain regions (e.g., source/drain regions 2702, 2702′, etc.) of the FET1 and the FET2 are formed in the sacrificial placeholder (e.g., sacrificial placeholder 2102). The sacrificial layers are removed from the first device stack and the second device stack. Gates (e.g., replacement metal gates 3002, 3002′, etc.) of the FET1 and the FET2 are formed that surround a portion of each of the active layers in a gate-all-around configuration. The sacrificial placeholder (e.g., sacrificial placeholder 2102) is replaced with wrap around source/drain contacts (e.g., wrap around source/drain contacts 3902, 3902′, etc.) that at least partially surround the source/drain regions (e.g., source/drain regions 2702, 2702′, etc.) of the FET1 and the FET2, whereby the dielectric bar is present between the gates (e.g., replacement metal gates 3002, 3002′, etc.) of the FET1 and the FET2, and between the source/drain regions (e.g., source/drain regions 2702, 2702′, etc.) of the FET1 and the FET2.

Techniques as disclosed herein can provide substantial beneficial technical effects. Some embodiments may not have these potential advantages and these potential advantages are not necessarily required of all embodiments. By way of example only and without limitation, one or more embodiments of the present semiconductor device can provide one or more of:
Efficient and effective “gate-cut first” techniques for semiconductor device fabrication that employ self-aligned gate isolation;
Increased contact area by way of contacts that at least partially wrap around source/drain regions of the semiconductor device; and
Built-in misalignment tolerances during contact formation.

As provided above, conventional semiconductor process flows typically involve first forming a gate, and then cutting the gate (i.e., forming a gate cut) between adjacent devices. Doing so, however, can require complex processes such as EUV lithography, the challenges of which are only exacerbated by increased scaling demands.

So called ‘gate-cut first’ techniques avoid these post-gate processing challenges by placing isolation elements, which serve as the gate cuts, prior to forming the gate itself. However, this approach alone can undesirably limit the area of the source/drain regions exposed for contact formation, thereby limiting contact area which can reduce device performance.

Advantageously, provided herein are techniques for easy and effective self-aligned gate isolation that is performed in accordance with a ‘gate-cut first’ process flow, whereby dielectric bars are placed between adjacent active areas early on in the process. Notably, as will be described in detail below, the present approach then involves the placement of a sacrificial ‘placeholder’ between the dielectric bars. Following formation of the source/drain regions, this sacrificial placeholder can then be selectively removed, thereby exposing an area around each of the source/drain regions. Doing so allows for the formation of contacts that can at least partially wrap around each of the source/drain regions, vastly increasing the contact area.

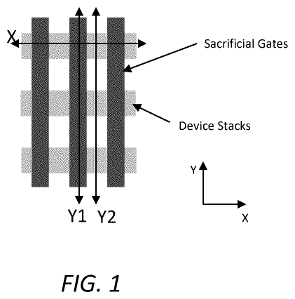

Given the above overview, an exemplary methodology for forming a semiconductor device in accordance with the present techniques is now described by way of reference to FIGS. 1-53. FIG. 1 (a top-down view) illustrates an overall layout of the present semiconductor device design. As shown in FIG. 1, the present semiconductor device includes at least one active area having, for example, device stacks of sacrificial/active layers on a frontside of a wafer (see below), and sacrificial gates disposed over, and oriented orthogonal to, the device stacks. The device stacks and sacrificial gates extend arbitrarily along an X-direction and a Y-direction, respectively. Accordingly, the X cross-sectional views provided herein represent cuts through the semiconductor device in the X-direction, i.e., along one of the device stacks. The Y1 cross-sectional views represent first cuts through the semiconductor device in the Y-direction, i.e., across the device stacks along one of the sacrificial gates. The Y2 cross-sectional views represent second cuts through the semiconductor device in the Y-direction, i.e., across the device stack between two of the sacrificial gates.

The term “sacrificial,” as used herein, generally refers to any material or structure that is used in one part of the process, and then later removed, in whole or in part, during fabrication of the semiconductor device. Thus, as would be apparent to one skilled in the art, a gate-last approach will be employed in the present example. With a gate-last approach, sacrificial gates are used as a placeholder during formation of the source/drain regions. The sacrificial gates are removed later on in the process, and replaced with the final gates of the device (also referred to herein as “replacement gates”). Thus, it is to be understood that the orientation of the replacement gates would be the same as that of the sacrificial gates shown in FIG. 1. When the replacement gates are metal gates, they may also be referred to herein as “replacement metal gates.” Advantageously, use of a gate-last process avoids exposing the replacement gate materials such as high-K dielectrics to potentially damaging conditions such as the high temperatures experienced during source/drain region formation.

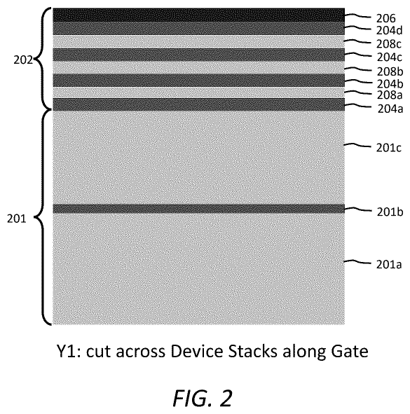

Referring to FIG. 2 (a Y1 cross-sectional view), the process begins with the formation of a stack 200 of sacrificial and active layers on a frontside of a wafer 201. According to an exemplary embodiment, wafer 201 includes a substrate 201a, an etch stop layer 201b disposed directly on the substrate 201a, and a semiconductor layer 201c disposed directly on the etch stop layer 201b. As will be described in detail below, etch stop layer 201b will be used during removal of the substrate 201a from a backside of the wafer 201. By way of example only, etch stop layer 201b can have a thickness of from about 2 nanometers (nm) to about 50 nm. According to one exemplary embodiment, substrate 201a is a bulk semiconductor wafer, such as a bulk silicon (Si) wafer, and etch stop layer 201b is formed from silicon germanium (SiGe) that is epitaxially grown from the (Si) substrate 201a. In turn, semiconductor layer 201c (e.g., Si) can be epitaxially grown from the etch stop layer 201b.

According to another exemplary embodiment, etch stop layer 201b is an oxide layer. In that case, wafer 201 can be a semiconductor-on-insulator or SOI wafer. An SOI wafer includes an SOI layer separated from an underlying substrate by a buried insulator. When the buried insulator is an oxide, it is also referred to herein as a buried oxide or BOX. In the present example, the substrate, BOX, and SOI layer correspond to the substrate 201a, the (oxide) etch stop layer 201b, and the semiconductor layer 201c, respectively. As above, the SOI layer/semiconductor layer 201c can include any suitable semiconductor material(s), such as Si.

According to an exemplary embodiment, the stack 200 of sacrificial and active layers includes alternating (first) sacrificial and active layers, and a top (second) sacrificial layer oriented horizontally one on top of another on wafer 201 (in particular, on semiconductor layer 201c of wafer 201). In one embodiment, the sacrificial and active layers are nanosheets. The term “nanosheet” as used herein, generally refers to a sheet or a layer having nanoscale dimensions. Further, the term “nanosheet” is meant to encompass other nanoscale structures such as nanowires. For instance, the term “nanosheet” can refer to a nanowire with a larger width, and/or the term “nanowire” can refer to a nanosheet with a smaller width, and vice versa.

For instance, as shown in FIG. 2, the stack 200 of sacrificial and active layers can include alternating layers of sacrificial layers 204a,b,c,d, etc. and active layers 208a,b,c, etc. disposed on the wafer 201, and a sacrificial layer 206 disposed on a top-most one of the sacrificial layers 204a,b,c,d, etc. For clarity, the terms “first” and “second” may also be used herein when referring to sacrificial layers 204a,b,c,d, etc. and sacrificial layer 206, respectively.

The present techniques involve the formation of field-effect transistors (FETs) of the semiconductor device on the frontside of the wafer 201 which, as will be described in detail below, includes removal of the (first) sacrificial layers 204a,b,c,d, etc. later on in the process to permit the formation of a gate-all-around or GAA configuration. By contrast, active layers 208a,b,c, etc. will remain in place and serve as channels of the FETs. As its name implies, the (second) sacrificial layer 206 will also be removed to enable the placement of an isolating dielectric. Advantageously, having sacrificial layer 206 in place at the top of the stack 200 of sacrificial and active layers will enable the formation of replacement metal gates of a uniform thickness surrounding the active layers 208a,b,c, etc. More specifically, having sacrificial layer 206 present over sacrificial layer 204d helps to protect that sacrificial layer 204d during subsequent processing. Thus, when sacrificial layers 204a,b,c,d, etc. are later removed, uniform gaps for the replacement metal gates are created between the active layers 208a,b,c, etc.

It is notable that the number of sacrificial layers 204a,b,c,d, etc. and active layers 208a,b,c, etc. shown in the figures is provided merely as an example to illustrate the present techniques. For instance, embodiments are contemplated herein where more or fewer sacrificial layers 204a,b,c,d, etc. and/or more or fewer active layers 208a,b,c, etc. are present than shown. According to an exemplary embodiment, each of the sacrificial layers 204a,b,c,d, etc., sacrificial layer 206, and active layers 208a,b,c, etc. is deposited/formed on semiconductor layer 201c of wafer 201 using an epitaxial growth process. According to an exemplary embodiment, each of the sacrificial layers 204a,b,c,d, etc., sacrificial layer 206, and active layers 208a,b,c, etc. has a thickness of from about 6 nm to about 25 nm.

The materials employed for the sacrificial layers 204a,b,c,d, etc. and active layers 208a,b,c, etc. are such that the sacrificial layers 204a,b,c,d, etc. can be removed selective to the active layers 208a,b,c, etc. during fabrication. Further, as highlighted above, the material employed for sacrificial layer 206 is such that sacrificial layer 206 can be removed selective to sacrificial layers 204a,b,c,d, etc. during fabrication in order to enable the formation of the isolating dielectric.

For instance, according to an exemplary embodiment, the sacrificial layers 204a,b,c,d, etc. are each formed from silicon germanium (SiGe), while the active layers 208a,b,c, etc. are each formed from silicon (Si). Etchants such as wet hot SC1, vapor phase hydrogen chloride (HCl), vapor phase chlorine trifluoride (ClF₃) and other reactive clean processes (RCP) are selective for etching of SiGe versus Si. This is, however, only one exemplary combination of sacrificial/active materials that may be employed in accordance with the present techniques. For instance, by way of example only, the opposite configuration can instead be implemented where the sacrificial layers 204a,b,c,d, etc. are each formed from Si, and the active layers 208a,b,c, etc. are each formed from SiGe.

Further, high germanium (Ge) content SiGe can be etched selective to low Ge content SiGe using an etchant such as dry HCl. Thus, according to an exemplary embodiment, sacrificial layer 206 is formed from SiGe having a high Ge content. For instance, in one exemplary embodiment, high Ge content SiGe is SiGe having from about 45% Ge to about 70% Ge. For instance, in one non-limiting example, sacrificial layer 206 is formed from SiGe55 (which is SiGe having a Ge content of about 55%). In that case, sacrificial layers 204a,b,c,d, etc. are preferably formed from a low Ge content SiGe. For instance, in one exemplary embodiment, low Ge content SiGe is SiGe having from about 15% Ge to about 35% Ge. For example, in one non-limiting embodiment, sacrificial layers 204a,b,c,d, etc. are formed from SiGe25 (which is SiGe having a Ge content of about 25%).

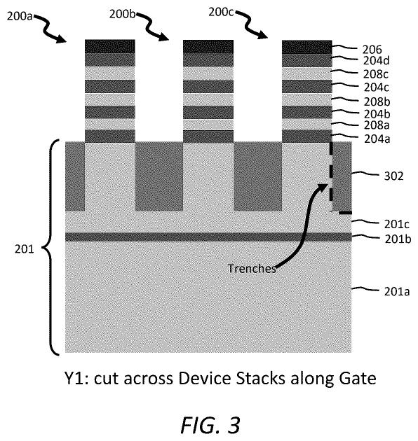

Referring to FIG. 3 (a Y1 cross-sectional view), the stack 200 of sacrificial and active layers is then patterned into individual device stacks 200a,b,c, etc., and shallow trench isolation (STI) regions 302 are formed in the wafer 201 between the device stacks 200a,b,c, etc. As will become apparent from the description that follows, these device stacks 200a,b,c, etc. correspond to a first field-effect transistor (FET1), a second FET (FET2), a third FET (FET3), etc. formed therefrom on the wafer 201.

Standard lithography and etching techniques can be employed to pattern the device stacks 200a,b,c, etc. With standard lithography and etching techniques, a lithographic stack (not shown), e.g., photoresist/anti-reflective coating/organic planarizing layer, is used to pattern a hardmask (not shown) with the footprint and location of each of the device stacks 200a,b,c, etc. Suitable hardmask materials include, but are not limited to, silicon nitride (SiN), silicon oxide (SiOₓ), titanium nitride (TiN) and/or silicon oxynitride (SiON). Alternatively, the hardmask can be formed by other suitable techniques, including but not limited to, sidewall image transfer (SIT), self-aligned double patterning (SADP), self-aligned quadruple patterning (SAQP), and other self-aligned multiple patterning (SAMP).

An etch is then used to transfer the pattern from the hardmask to the stack 200 of sacrificial and active layers to form the device stacks 200a,b,c, etc. Device stacks 200a,b,c, etc. are representative of the ‘Device Stacks’ depicted in FIG. 1. Suitable etching processes include, but are not limited to, directional (anisotropic) etching processes such as reactive ion etching (RIE). As shown in FIG. 3, the etch used to pattern the device stacks 200a,b,c, etc. extends into the semiconductor layer 201c, forming trenches in the wafer 201 between the device stacks 200a,b,c, etc. For clarity, a dashed outline is used in FIG. 3 to illustrate one of these trenches, with the understanding that a trench is present at the location of each of the STI regions 302.

The STI regions 302 are then formed in the trenches between the device stacks 200a,b,c, etc. STI regions 302 serve to isolate the device stacks 200a,b,c, etc. To form the STI regions 302, a dielectric such as an oxide (which may also be generally referred to herein as a ‘shallow trench isolation (STI) oxide’) is deposited into, and filling, the trenches, followed by planarization and recess. Although not explicitly shown in the figures, a liner (e.g., a thermal oxide or silicon nitride (SiN)) may be deposited into the trenches prior to the shallow trench isolation oxide. Suitable shallow trench isolation oxides include, but are not limited to, oxide low-κ materials such as silicon oxide (SiOₓ) and/or oxide ultralow-κ interlayer dielectric (ULK-ILD) materials, e.g., having a dielectric constant κ of less than 2.7. Suitable ultralow-K dielectric materials include, but are not limited to, porous organosilicate glass (pSiCOH). A process such as chemical vapor deposition (CVD), atomic layer deposition (ALD), or physical vapor deposition (PVD) can be employed to deposit the shallow trench isolation oxide, after which the shallow trench isolation oxide can be planarized using a process such as chemical mechanical polishing (CMP). After that, the shallow trench isolation oxide can be recessed using a dry or wet etch process to form the STI regions 302 at a base of each of the device stacks 200a,b,c, etc.

As highlighted above, the present techniques employ a ‘gate-cut first’ process flow, whereby dielectric bars (for gate isolation) are placed between adjacent active areas, i.e., between the device stacks 200a,b,c, etc., prior to gate formation. Notably, these dielectric bars are self-aligned to the subsequently-formed gates. As also highlighted above, the subsequently-formed gates will have a GAA configuration, which means that they surround at least a portion of each of the active layers 208a,b,c, etc. To do so, the dielectric bars need to be offset from the device stacks 200a,b,c, etc. which, according to an exemplary embodiment, is done using a sacrificial spacer.

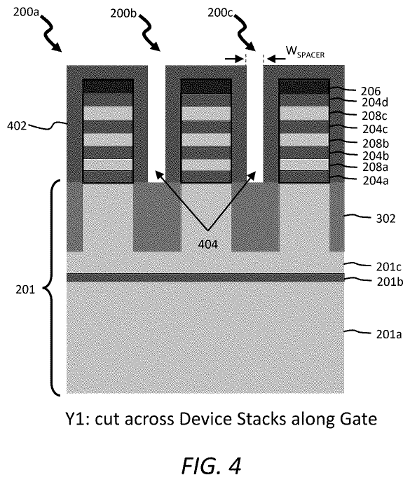

Namely, referring to FIG. 4 (a Y1 cross-sectional view), sacrificial spacers 402 are selectively formed along a top and sidewalls of each of the device stacks 200a,b,c, etc. According to an exemplary embodiment, the sacrificial spacers 402 are epitaxially grown, thereby limiting where the sacrificial spacers 402 are formed, namely on the exposed top and sidewall surfaces of each of the device stacks 200a,b,c, etc. More specifically, following patterning of the device stacks 200a,b,c, etc., surfaces of the sacrificial layers 204a,b,c,d, etc./sacrificial layer 206 and active layers 208a,b,c, etc. are exposed along the sidewalls of each of the device stacks 200a,b,c, etc., and a surface of the sacrificial layer 206 is exposed along the top of each of the device stacks 200a,b,c, etc. See FIG. 3, described above. It is on these surfaces, and only on these surfaces, that the sacrificial spacers 402 will then be (selectively) deposited/grown.

Preferably, the sacrificial spacers 402 are formed from the same material as the sacrificial layers 204a,b,c,d, etc. For instance, as provided above, embodiments are contemplated herein where the sacrificial layers 204a,b,c,d, etc. are formed from a low Ge content SiGe, i.e., SiGe having from about 15% Ge to about 35% Ge, such as SiGe25. In that case, the sacrificial spacers 402 can also be formed from a low Ge content SiGe, i.e., SiGe having from about 15% Ge to about 35% Ge, such as SiGe25. That way, the sacrificial layers 204a,b,c,d, etc. and the sacrificial spacers 402 can be removed concurrently during replacement metal gate formation, as described in detail below.

Further, as shown in FIG. 4, spaces 404 are left between the sacrificial spacers 402 on adjacent device stacks 200a,b,c, etc. According to an exemplary embodiment, each of the spaces 404 has a width W_{SPACE} of from about 2 nm to about 10 nm. It is in these spaces 404 that the dielectric bars are formed.

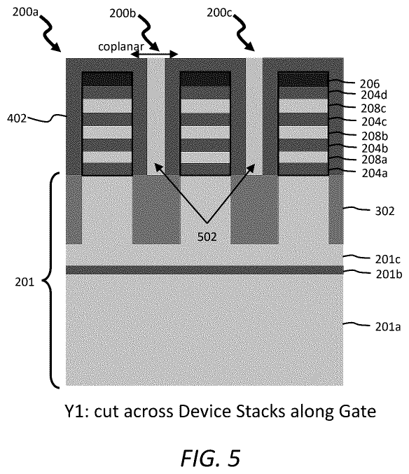

Namely, referring to FIG. 5 (a Y1 cross-sectional view), dielectric bars 502 are formed in the spaces 404 between the sacrificial spacers 402 on adjacent device stacks 200a,b,c, etc. Suitable dielectric materials for the dielectric bars 502 include, but are not limited to, SiOx, silicon carbide (SiC), silicon oxycarbide (SiCO), SiN, silicoboron carbonitride (SiBCN) and/or silicon oxycarbonitride (SiOCN), which can be deposited into the spaces 404 using a process such as CVD, ALD or PVD. Following deposition, the overburden can be removed using a process such as CMP. As shown in FIG. 5, the resulting dielectric bars 502 are present only between the adjacent device stacks 200a,b,c, etc., and are centered/aligned over, and directly contact, the STI regions 302. In other words, the dielectric bars 502 are self-aligned to the area between the device stacks 200a,b,c, etc. In accordance with the present techniques, it is these dielectric bars 502 that will provide self-aligned gate isolation. According to an exemplary embodiment, the top surfaces of the dielectric bars 502 are coplanar with the top surfaces of the sacrificial spacers 402.

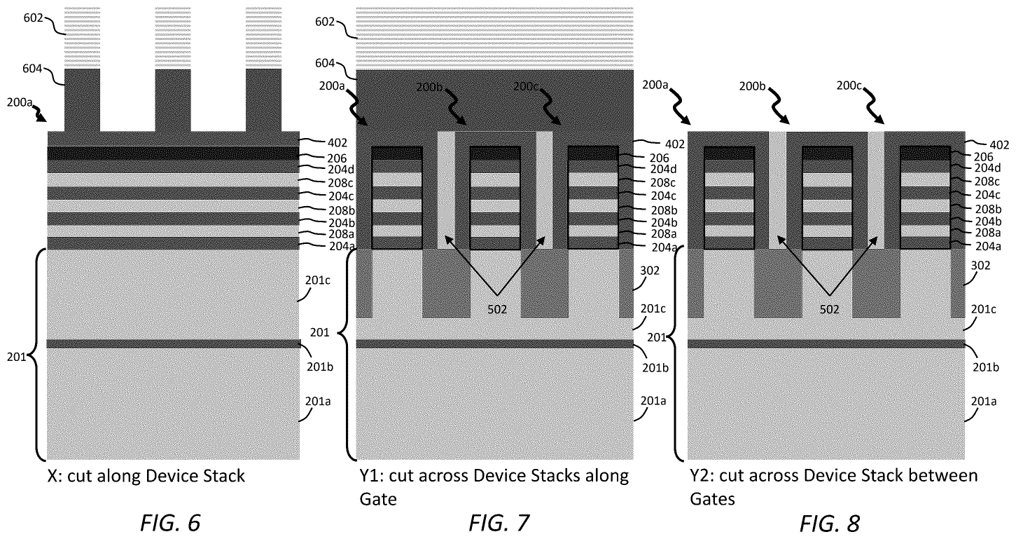

Referring to FIG. 6 (an X cross-sectional view), FIG. 7 (a Y1 cross-sectional view) and FIG. 8 (a Y2 cross-sectional view), sacrificial gates 604 are next formed on the device stacks 200a,b,c, etc. To form the sacrificial gates 604, a sacrificial gate material is first blanket deposited over the device stacks 200a,b,c, etc. Suitable sacrificial gate materials include, but are not limited to, poly-silicon and/or amorphous silicon. A process such as CVD, ALD or PVD can be employed to deposit the sacrificial gate material over the device stacks 200a,b,c, etc. According to an exemplary embodiment, a thin (e.g., from about 1 nm to about 3 nm) layer of SiOx (not shown) is first formed on the device stacks 200a,b,c, etc., followed by deposition of the poly-silicon and/or amorphous silicon.

Standard lithography and etching techniques (see above) are used to form sacrificial gate hardmasks 602 on the sacrificial gate material marking the footprint and location of each of the sacrificial gates 604. As provided above, suitable hardmask materials include, but are not limited to, SiN, SiO₂, TiN and/or SiON. An etch using the sacrificial gate hardmasks 602 is then used to pattern the sacrificial gate material into the individual sacrificial gates 604 shown in FIGS. 6 and 7. Sacrificial gates 604 are representative of the ‘Sacrificial Gates’ depicted in FIG. 1.

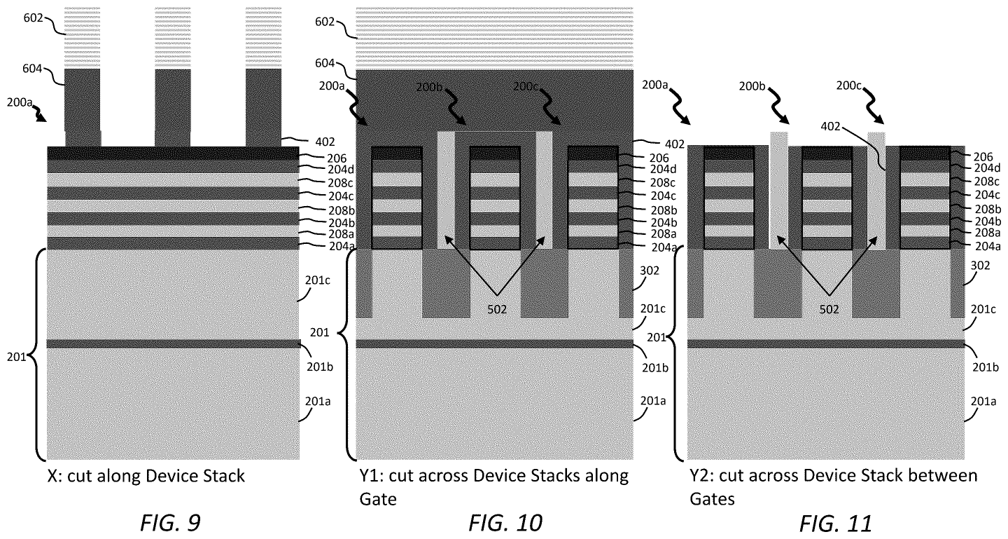

Referring to FIG. 9 (an X cross-sectional view), FIG. 10 (a Y1 cross-sectional view) and FIG. 11 (a Y2 cross-sectional view), an etch is employed to recess the sacrificial spacers 402 down to the sacrificial layer 206. As highlighted above, sacrificial layer 206 serves to cover/protect the underlying sacrificial layer 204d during this recess etch. According to an exemplary embodiment, this recess etch is performed using a SiGe-selective RIE process. As such, those portions of the sacrificial spacers 402 covered by the sacrificial gate hardmasks 602 and sacrificial gates 604 remain unaffected. Sec, for example, FIG. 9 where the only remaining portions of the sacrificial spacers 402 above the sacrificial layer 206 are those covered by the sacrificial gate hardmasks 602 and sacrificial gates 604.

As shown in FIG. 11, recess of the sacrificial spacers 402 in a source/drain area (i.e., area in which the source/drain regions of the semiconductor device will be formed (see below)) results in the dielectric bars 502 extending above the (recessed) sacrificial spacers 402. By comparison, as shown in FIG. 10, in the regions of the semiconductor device covered by sacrificial gate hardmasks 602 and sacrificial gates 604, the top surfaces of the dielectric bars 502 remain coplanar with the top surfaces of the sacrificial spacers 402.

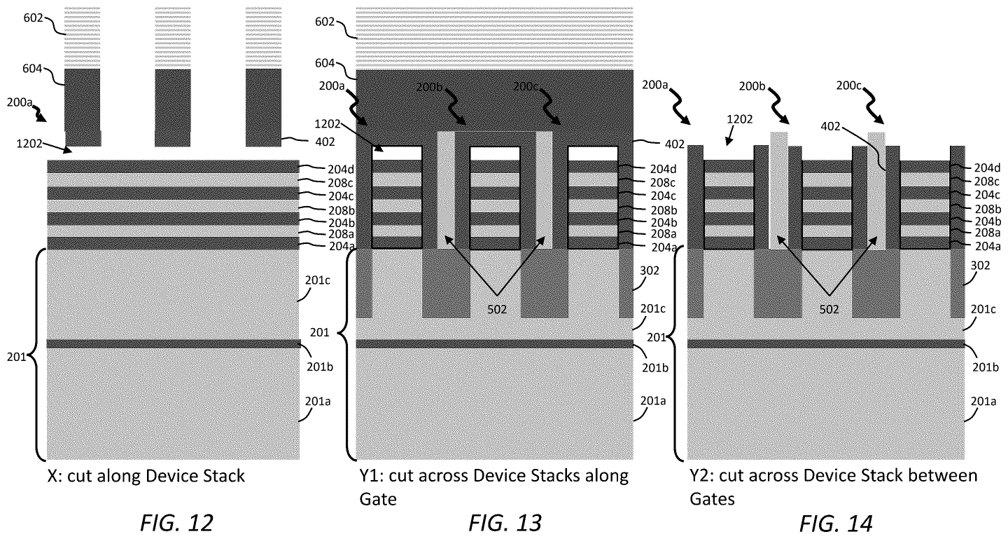

Recess of the sacrificial spacers 402 exposes the underlying sacrificial layer 206, which next enables the selective removal of the sacrificial layer 206. Namely, referring to FIG. 12 (an X cross-sectional view), FIG. 13 (a Y1 cross-sectional view) and FIG. 14 (a Y2 cross-sectional view), the sacrificial layer 206 is then selectively removed.

As provided above, the sacrificial layer 206 can be formed from SiGe having a high Ge content, i.e., SiGe having from about 45% Ge to about 70% Ge (such as SiGe55), whereas the sacrificial layers 210a,b,c, etc. can be formed from low Ge content SiGe, i.e., SiGe having from about 15% Ge to about 35% Ge (such as SiGe25). In that case, the sacrificial layer 206 can be selectively removed using an etchant such as dry HCl. As shown in FIGS. 12-14, removal of the sacrificial layer 206 creates cavities 1202 in the device stacks 200a,b,c, etc.

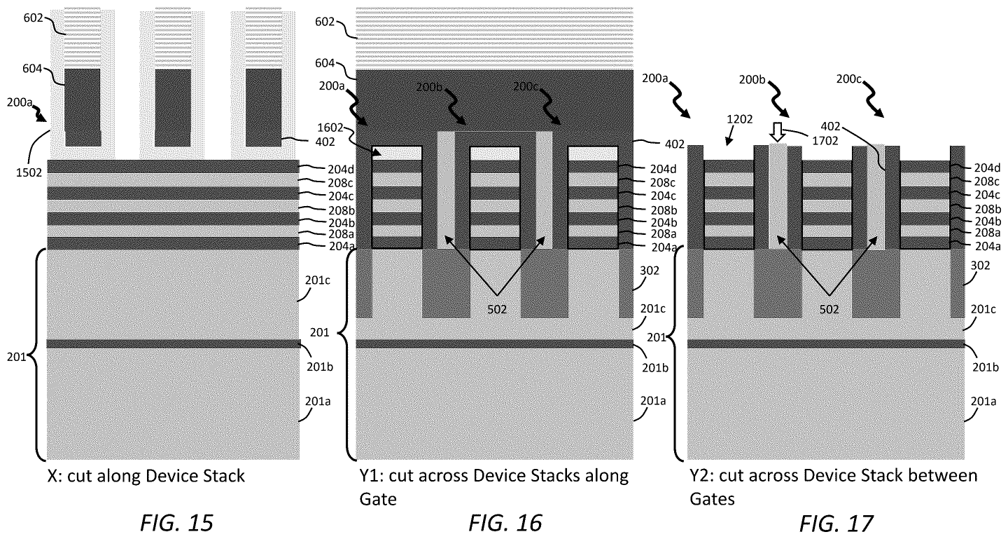

Referring to FIG. 15 (an X cross-sectional view), FIG. 16 (a Y1 cross-sectional view) and FIG. 17 (a Y2 cross-sectional view), a dielectric spacer material is then deposited over the device stacks 200a,b,c, etc. and into/filling the cavities 1202, followed by a directional (anisotropic) spacer etching process such as RIE to pattern the dielectric spacer material into an isolating dielectric 1602 in the cavities 1202 and dielectric spacers 1502 alongside the sacrificial spacers 402, the sacrificial gate hardmasks 602 and sacrificial gates 604. Suitable dielectric spacer materials include, but are not limited to, SiOx, SiC, SiCO, SiN, SiBCN and/or SiOCN, which can be deposited using a process such as CVD, ALD or PVD. The dielectric spacer material may be the same as, or different from, the dielectric material employed for the dielectric bars 502 (see above).

Notably, as shown particularly in FIG. 17, this spacer etch will remove the dielectric spacer material deposited into the cavities 1202 in the source/drain area (i.e., area in which the source/drain regions of the semiconductor device will be formed (see below)). Further, with this spacer etch, there is expected to be some loss to a height of the dielectric bars 502 in the source/drain area. Sec arrow 1702. By comparison, portions of the dielectric bars 502 covered by the sacrificial gate hardmasks 602 and sacrificial gates 604 remain unaffected. See, for example, FIG. 16. As will be described in detail below, this height differential of the dielectric bars 502 in different regions of the semiconductor device is a unique feature of the present design.

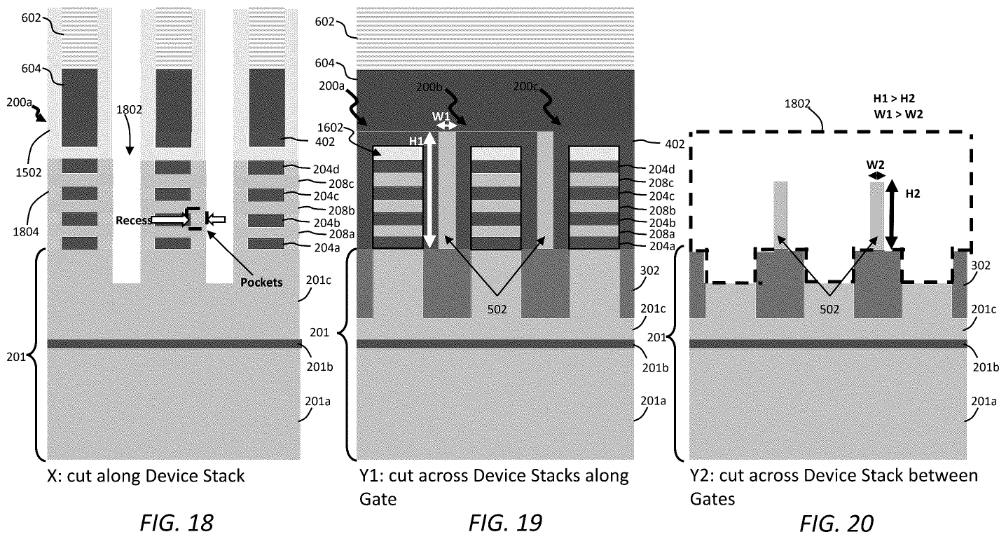

Referring to FIG. 18 (an X cross-sectional view), FIG. 19 (a Y1 cross-sectional view) and FIG. 20 (a Y2 cross-sectional view), sacrificial gate hardmasks 602, sacrificial gates 604 and dielectric spacers 1502 are then used as a mask to pattern trenches 1802 in the device stacks 200a,b,c, etc. and wafer 201 between the sacrificial gates 604, and inner spacers 1804 are formed alongside the sacrificial layers 204a,b,c,d, etc. within the trenches 1802. A directional (anisotropic) etching process such as RIE can be employed for etching the trenches 1802. As shown particularly in FIG. 18, the trenches 1802 can extend into the underlying semiconductor layer 201c below the device stacks 200a,b,c, etc.

As shown particularly in FIG. 20, the etch of trenches 1802 will remove what remains of the device stacks 200a,b,c, etc. in the source/drain area (i.e., area in which the source/drain regions of the semiconductor device will be formed (see below)). The trenches 1802 in this region are depicted with a dashed outline and, as described above, can extend into the underlying semiconductor layer 201c. It is in the trenches 1802 that the present sacrificial placeholder will be deposited which will ultimately enable the formation of the instant wrap around source/drain contacts.

To form the inner spacers 1804, a selective lateral etch is performed to first recess the sacrificial layers 204a,b,c,d, etc. exposed along sidewalls of the trenches 1802. This recess etch forms pockets along the sidewalls of the trenches 1802 that are then filled with a dielectric spacer material to form the inner spacers 1804 within the pockets. See, e.g., FIG. 18. The inner spacers 1804 will serve to offset the replacement gates from the source/drain regions (see below). As provided above, sacrificial layers 204a,b,c,d, etc. can be formed from SiGe. In that case, a SiGe-selective non-directional (isotropic) etching process can be used for the recess etch. Suitable dielectric spacer materials for inner spacers 1804 include, but are not limited to, silicon nitride (SiN), SiOx, SiC and/or SiCO. A process such as CVD, ALD or PVD can be employed to deposit the dielectric spacer material into the pockets, after which excess spacer material can be removed from the trenches 1802 using an isotropic etching process such as RIE.

Notably, the above-described etching of trenches 1802 and formation of the inner spacers 1804 will likely result in the height (H) and/or width (W) of the dielectric bars 502 in the source/drain area (i.e., area in which the source/drain regions of the semiconductor device will be formed (see below)). Compare, for example, FIG. 19 and FIG. 20. Namely, as shown in FIG. 19, regions of the dielectric bars 502 beneath the sacrificial gate hardmasks 602/sacrificial gates 604 have a first height H1 and a first width W1. By comparison, as shown in FIG. 20, other regions of the dielectric bars 502 in the source/drain area have a second height H2 and a second width W2, where H1 is greater than H2 (i.e., H1>H2) and W1 is greater than W2 (i.e., W1>W2). This variation in width and/or height of the dielectric bars 502 in different regions of the semiconductor device is a distinct and unique feature of the present design.

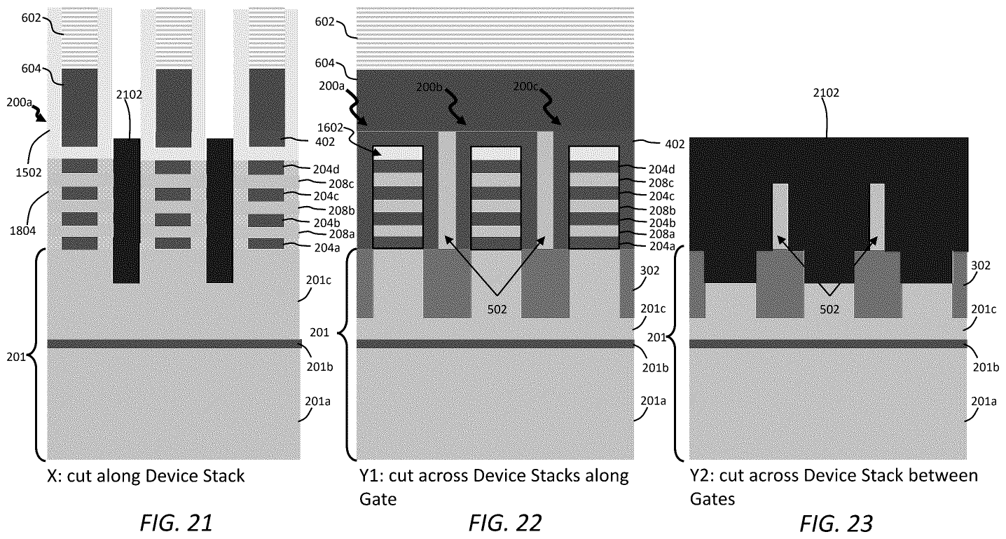

Referring to FIG. 21 (an X cross-sectional view), FIG. 22 (a Y1 cross-sectional view) and FIG. 23 (a Y2 cross-sectional view), a sacrificial placeholder 2102 is deposited into the trenches 1802 adjacent to the device stacks 200a,b,c, etc. As shown particularly in FIG. 23, the sacrificial placeholder 2102 is deposited over the dielectric bars 502 in the source/drain area (i.e., area in which the source/drain regions of the semiconductor device will be formed (see below)). Suitable sacrificial placeholder 2102 materials include, but are not limited to, titanium oxide (TiOₓ), aluminum oxide (AlOₓ) and/or amorphous germanium. A process such as CVD, ALD or PVD can be employed to deposit the sacrificial placeholder 2102 material, after which the sacrificial placeholder 2102 material can be recessed using a using an isotropic etching process such as RIE.

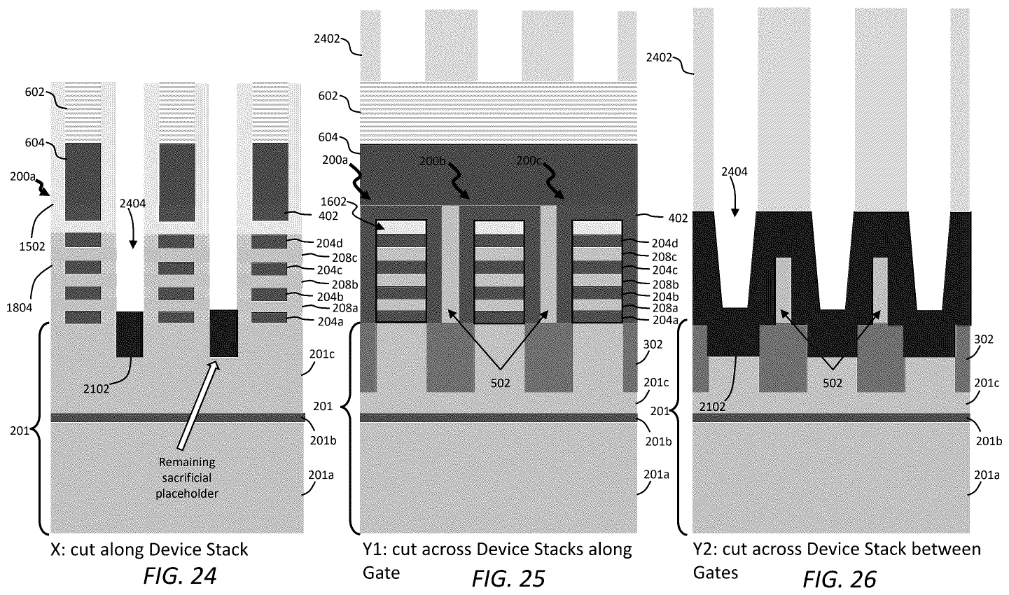

Referring to FIG. 24 (an X cross-sectional view), FIG. 25 (a Y1 cross-sectional view) and FIG. 26 (a Y2 cross-sectional view), source/drain cavities 2404 are then patterned in the sacrificial placeholder 2102. As their name implies, it is in the source/drain cavities 2404 that the source/drain regions of the semiconductor device will be epitaxially grown (see below).

To form the source/drain cavities 2404, standard lithography and etching techniques can be used to pattern a block mask 2402 with the footprint and location of each of the source/drain cavities 2404. Suitable materials for the block mask 2402 include, but are not limited to organic planarizing layer materials. A directional (anisotropic) etching processes such as RIE can then be employed to transfer the pattern to the sacrificial placeholder 2102 to form the source/drain cavities 2404 therein. Following formation of the source/drain cavities 2404, the block mask 2402 can be removed. For instance, when the block mask 2402 is formed from an organic planarizing layer material, the block mask 2402 can be removed using a process such as ashing.

As shown particularly in FIG. 24, it is preferable that portions of the sacrificial placeholder 2102 remain at the bottom of the source/drain cavities 2404 (i.e., between the source/drain cavities 2404 and the wafer 201). This will enable the formation of the instant wrap around source/drain contacts to fully surround the source/drain regions when the sacrificial placeholder 2102 is subsequently removed (see below). Further, as shown particularly in FIG. 26, the source/drain cavities 2404 are formed in between the dielectric bars 502 in the source/drain area (i.e., area in which the source/drain regions of the semiconductor device will be formed (see below)). In this example, the source/drain cavities 2404 are aligned with the dielectric bars 502. However, as will be described in conjunction with an alternate embodiment below, some misalignment tolerance is built in to the present process, such that perfect alignment of the source/drain cavities is not required.

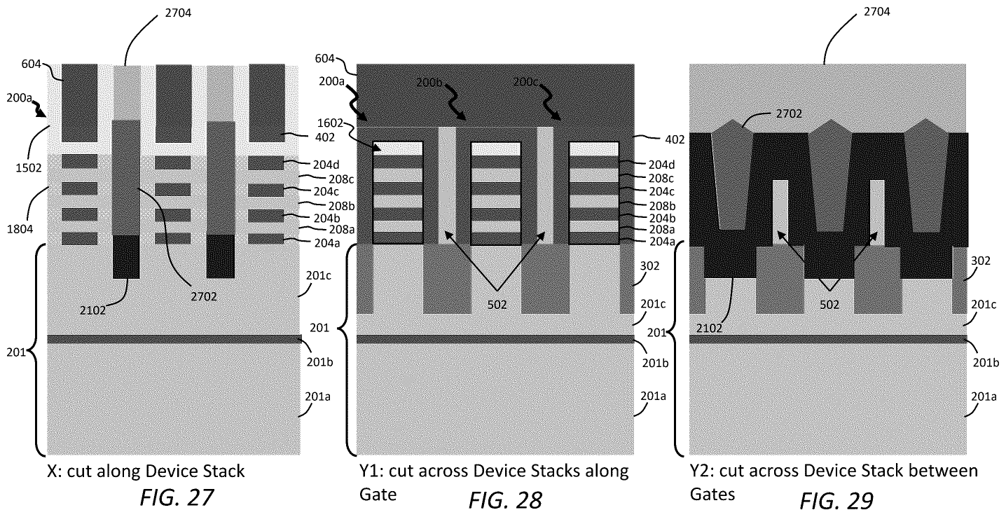

Referring to FIG. 27 (an X cross-sectional view), FIG. 28 (a Y1 cross-sectional view) and FIG. 29 (a Y2 cross-sectional view), source/drain regions 2702 are formed in the source/drain cavities 2404 of the sacrificial placeholder 2102 on opposite sides of the sacrificial gates 604 alongside the sacrificial layers 204a,b,c,d, etc. and active layers 208a,b,c, etc., an interlayer dielectric 2704 is deposited onto the semiconductor device structure, and the sacrificial gate hardmasks 602 are removed.

According to an exemplary embodiment, the source/drain regions 2702 are formed from an in-situ doped (i.e., during growth) or ex-situ doped (e.g., via ion implantation) epitaxial material such as epitaxial Si, epitaxial SiGe, etc. Suitable p-type dopants include, but are not limited to, boron (B). Suitable n-type dopants include, but are not limited to, phosphorous (P) and/or arsenic (As). With inner spacers 1804 in place along the sidewalls of the device stacks 200a,b,c, etc., epitaxial growth of the source/drain regions 2702 is templated only from the ends of the active layers 208a,b,c, etc. along the sidewalls of the device stacks 200a,b,c, etc.

Suitable interlayer dielectric 2704 materials include, but are not limited to, silicon nitride (SiN), silicon oxycarbide (SiOC) and/or oxide low-K materials such as SiOx and/or oxide ULK-ILD materials such as pSICOH, which can be deposited onto the semiconductor device structure using a process such as CVD, ALD or PVD. Following deposition, the interlayer dielectric 2704 can be planarized using a process such as CMP. According to an exemplary embodiment, this CMP serves to remove the sacrificial gate hardmasks 602 thereby exposing the underlying sacrificial gates 604.

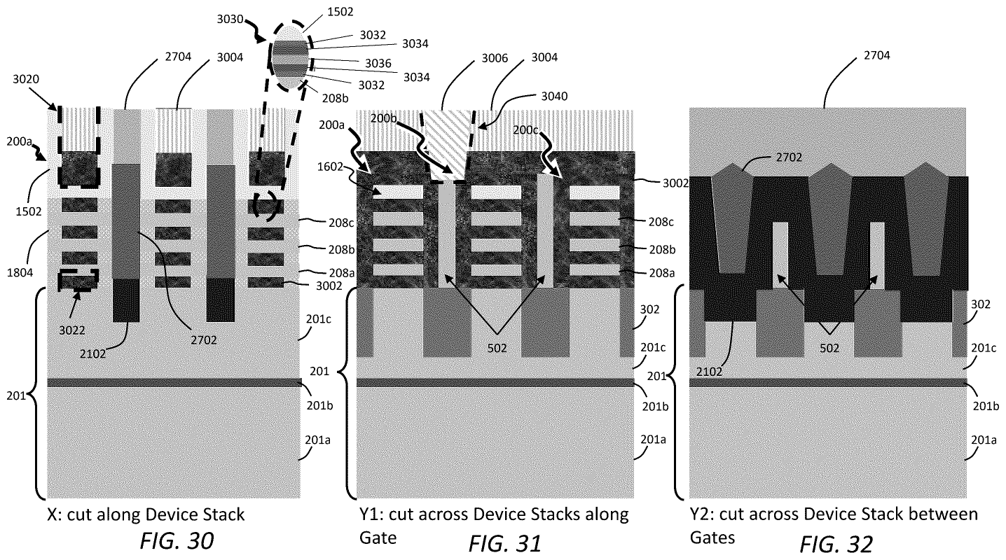

Referring to FIG. 30 (an X cross-sectional view), FIG. 31 (a Y1 cross-sectional view) and FIG. 32 (a Y2 cross-sectional view), the sacrificial gates 604 are selectively removed, the sacrificial layers 204a,b,c,d, etc. along with the sacrificial spacers 402 are selectively removed from the device stacks 200a,b,c, etc. thereby releasing the active layers 208a,b,c, etc., replacement metal gates 3002 are formed, dielectric caps 3004 are formed over the replacement metal gates 3002, and a gate divider 3006 is formed at a top of the replacement metal gates 3002. Specifically, as shown, for example, in FIG. 30, removal of the sacrificial gates 604 forms gate trenches 3020 in the interlayer dielectric 2704 over the device stacks 200a,b,c, etc. in between the source/drain regions 2702. The sacrificial layers 204a,b,c,d, etc., now accessible through the gate trenches 3020, are then selectively removed creating gaps 3022 in the device stacks 200a,b,c, etc. between the active layers 208a,b,c, etc. According to an exemplary embodiment, the sacrificial layers 204a,b,c,d, etc. are formed from SiGe, while the active layers 208a,b,c, etc. are formed from Si. In that case, etchants such as wet hot SC1, vapor phase HCl, vapor phase ClF₃ and/or other reactive clean processes can be employed to remove the sacrificial layers 204a,b,c,d, etc., selective to the active layers 208a,b,c, etc. Removal of the sacrificial layers 204a,b,c,d, etc. releases the active layers 208a,b,c, etc. from the device stacks 200a,b,c, etc. These ‘released’ active layers 208a,b,c, etc. will be used to form the channels of the semiconductor device.

The replacement metal gates 3002 are then formed in the gate trenches 3020 and the gaps 3022 surrounding a portion of each of the active layers 208a,b,c, etc. in a gate-all-around or GAA configuration. The term ‘gates’ may also be used herein when referring to replacement metal gates 3002. Referring to magnified view 3030 in FIG. 30, according to an exemplary embodiment, formation of the replacement metal gates 3002 begins with the deposition of a (conformal) gate dielectric 3032 into and lining each of the gate trenches 3020 and the gaps 3022. In one embodiment, gate dielectric 3032 is a high-K material. The term “high-K,” as used herein, refers to a material having a relative dielectric constant κ which is much higher than that of silicon dioxide (e.g., a dielectric constant κ=25 for hafnium oxide (HfO₂) rather than 4 for SiO₂). Suitable high-κ gate dielectrics include, but are not limited to, hafnium oxide (HfO₂) and/or lanthanum oxide (La₂O₃). A process such as CVD, ALD or PVD can be employed to deposit the gate dielectric 3032. According to an exemplary embodiment, gate dielectric 3032 has a thickness of from about 1 nanometer (nm) to about 5 nm. A reliability anneal can be performed following deposition of gate dielectric 3032. This reliability anneal can be performed at a temperature of from about 500 degrees Celsius (C) to about 1200° C., for a duration of from about 1 nanosecond to about 30 seconds. Preferably, the reliability anneal is performed in the presence of an inert gas such as, but not limited to, nitrogen.

At least one workfunction-setting metal 3034 is then deposited into the gate trenches 3020 and the gaps 3022 over the gate dielectric 3032. Suitable n-type workfunction-setting metals include, but are not limited to, titanium nitride (TiN), tantalum nitride (TaN) and/or aluminum (Al)-containing alloys such as titanium aluminide (TiAl), titanium aluminum nitride (TiAlN), titanium aluminum carbide (TiAlC), tantalum aluminide (TaAl), tantalum aluminum nitride (TaAlN), and/or tantalum aluminum carbide (TaAlC). Suitable p-type workfunction-setting metals include, but are not limited to, TiN, TaN, and/or tungsten (W). TiN and TaN are relatively thick (e.g., greater than about 2 nm) when used as p-type workfunction-setting metals. However, very thin TiN or TaN layers (e.g., less than about 2 nm) may also be used beneath Al-containing alloys in n-type workfunction-setting stacks to improve electrical properties such as gate leakage currents. Thus, there is some overlap in the exemplary n- and p-type workfunction-setting metals given above. A process such as CVD, ALD or PVD can be employed to deposit the workfunction-setting metal(s) 3034, after which the metal overburden can be removed using a process such as CMP.

Optionally, a low-resistance fill metal 3036 can be deposited into the gate trenches 3020 and the gaps 3022 over the workfunction-setting metal(s) 3034 so as to fill in any remaining spaces in the replacement metal gates 3002. Suitable low-resistance fill metals 3036 include, but are not limited to, W, cobalt (Co), ruthenium (Ru) and/or Al which can be deposited using a process or combination of processes including, but not limited to, CVD, ALD, PVD, sputtering, plating, evaporation, ion beam deposition, electron beam deposition, laser assisted deposition, chemical solution deposition, etc.

The replacement metal gates 3002 are then recessed, and the dielectric caps 3004 are formed over the (recessed) replacement metal gates 3002. Suitable materials for the dielectric caps 3004 include, but are not limited to, SiOx and/or SiN, which can be deposited using a process such as CVD, ALD or PVD. Following deposition, the material can be planarized using a process such as CMP.

Standard lithography and etching techniques (see above) can be employed to pattern an opening 3040 in the replacement metal gates 3002 and dielectric caps 3004 as shown, for example, in FIG. 31. A dielectric material is then deposited into the opening 3040 to form gate divider 3006 at the top of the replacement metal gates 3002. Suitable dielectric materials include, but are not limited to, SiN, SiOx, SiC and/or SiCO, which can be deposited into the opening 3040 using a process such as CVD, ALD or PVD. Following deposition, excess dielectric material can be removed using a process such as CMP.

As highlighted above, the present techniques employ a gate-cut first process where dielectric bars 502 are placed prior to the replacement metal gates 3002. As such, following formation of the replacement metal gates 3002, only a shallow gate divider 3006 is needed to complete isolation of the adjacent replacement metal gates 3002. Namely, with a conventional approach to cut an already-formed gate there would be no structures such as the present dielectric bars 502 already in place, and thus a complex and costly etching process such as EUV lithography would be needed to create a deep gate cut opening, i.e., one that extends all the way down to the STI regions 302. By comparison, with the present approach, the gate divider 3006 is shallow meaning that it only has to extend down far enough to contact the top of the dielectric bars 502 which, as shown in FIG. 31, is at about the same height as the isolating dielectric 1602 at the top of the device stacks 200a,b,c, etc.

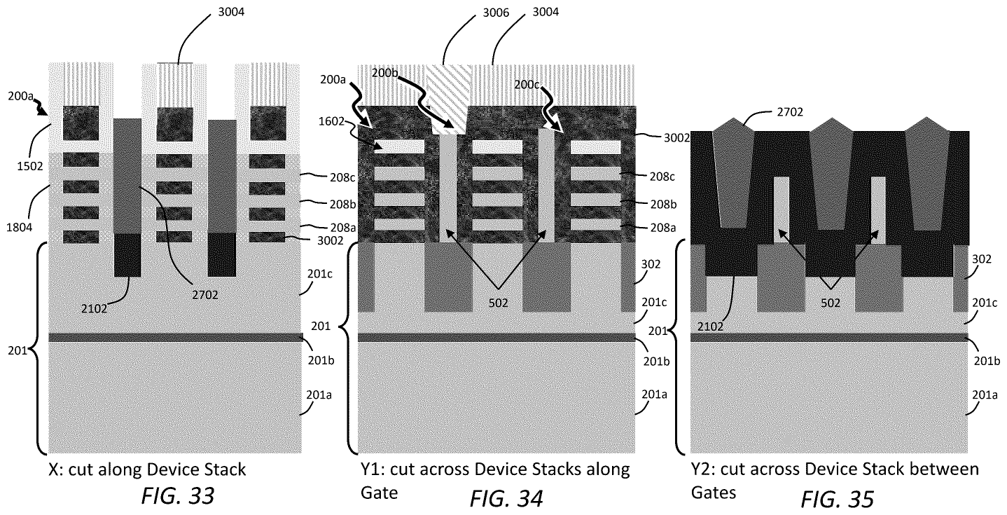

Referring to FIG. 33 (an X cross-sectional view), FIG. 34 (a Y1 cross-sectional view) and FIG. 35 (a Y2 cross-sectional view), the interlayer dielectric 2704 is recessed to expose the underlying sacrificial placeholder 2102. As provided above, the interlayer dielectric 2704 can be formed from a nitride or oxide material. In that case, a nitride- or oxide-selective etching process, as the case may be, can be employed to recess the interlayer dielectric 2704.

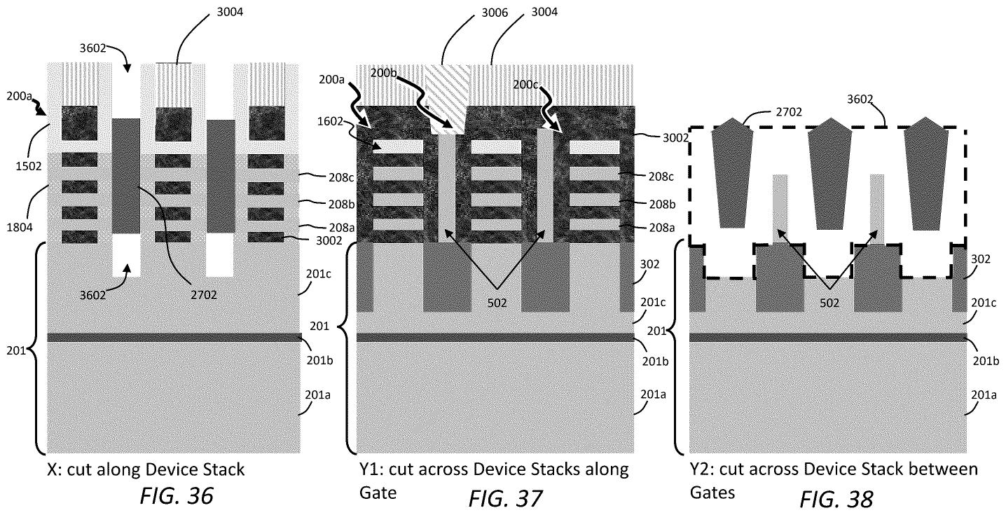

Referring to FIG. 36 (an X cross-sectional view), FIG. 37 (a Y1 cross-sectional view) and FIG. 38 (a Y2 cross-sectional view), the (now-exposed) sacrificial placeholder 2102 is then selectively removed forming openings 3602 surrounding the source/drain regions 2702. These openings 3602 surrounding the source/drain regions 2702 of the semiconductor device are depicted with a dashed outline, as shown particularly in FIG. 38. For instance, when the sacrificial placeholder 2102 is formed from an oxide material (see above), an oxide-selective etching process can be employed to selectively remove the sacrificial placeholder 2102. For instance, a high passivating RIE process can be used with a gas such as hydrogen bromide (HBr), oxygen (O₂) and/or perfluorocyclobutane (C₄F₈) to improve oxide-selectivity. An amorphous germanium-selective etching process can be similarly employed. For instance, oxidation can be used to form germanium oxide (GeO₂), which can then be selectively removed using a wet etching process with a hydrogen fluoride (HF)-based solution. The sacrificial placeholder 2102 can then be replaced with the present wrap around source/drain contacts.

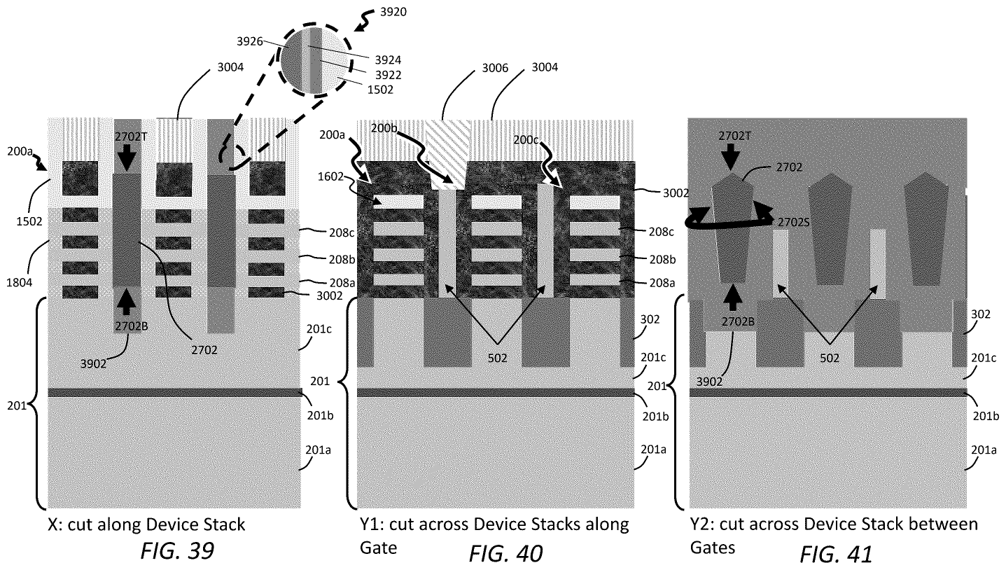

Namely, referring to FIG. 39 (an X cross-sectional view), FIG. 40 (a Y1 cross-sectional view) and FIG. 41 (a Y2 cross-sectional view), contact metallization is then used to form wrap around source/drain contacts 3902 in the openings 3602. Referring to magnified view 3920 in FIG. 39, this contact metallization can include first depositing a silicide liner 3922 into and lining the openings 3302, depositing a metal adhesion layer 3924 onto the silicide liner 3922, and then depositing a fill metal 3926 onto the metal adhesion layer 3924. Suitable silicide liner 3922 materials include, but are not limited to, titanium (Ti), nickel (Ni) and/or nickel platinum (NiPt), which can be deposited using a process such as CVD, ALD or PVD. According to an exemplary embodiment, silicide liner 3922 has a thickness of from about 1 nm to about 5 nm. Suitable metal adhesion layer 3924 materials include, but are not limited to, TiN and/or TaN, which can be deposited onto the silicide liner 3922 using a process such as CVD, ALD or PVD. According to an exemplary embodiment, metal adhesion layer 3924 has a thickness of from about 1 nm to about 5 nm. Suitable fill metals 3926 include, but are not limited to, W, Co, Ru and/or Al, which can be deposited onto the metal adhesion layer 3924 using a process such as CVD, ALD, PVD, sputtering, plating, evaporation, ion beam deposition, electron beam deposition, laser assisted deposition, chemical solution deposition, etc. Following deposition, the overburden can be removed using a process such as CMP.

Notably, as shown particularly in FIG. 39 and FIG. 41, the resulting wrap around source/drain contacts 3902 fully surround each of the (epitaxial) source/drain regions 2702. More specifically, in this example, wrap around source/drain contacts 3902 directly contact a bottom 2702B, a top 2702T, and opposing sidewalls 2702S of each of the source/drain regions 2702. As such, advantageously, the present wrap around source/drain contacts 3902 vastly increase the contact area as opposed to conventional designs where access is often limited to the tops of the source/drain regions.

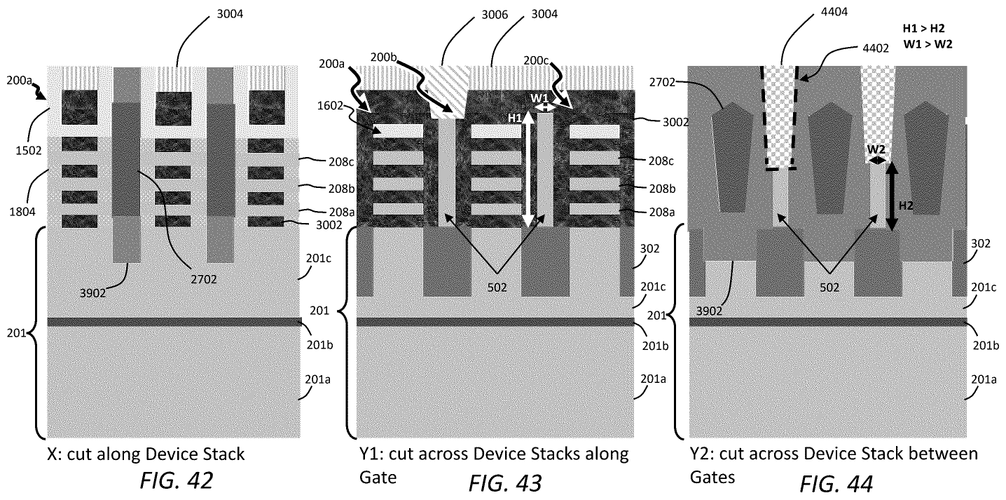

Referring to FIG. 42 (an X cross-sectional view), FIG. 43 (a Y1 cross-sectional view) and FIG. 44 (a Y2 cross-sectional view), contact dividers 4404 are formed at a top of the wrap around source/drain contacts 3902. Standard lithography and etching techniques (see above) can be employed to pattern openings 4402 in the wrap around source/drain contacts 3902 between adjacent source/drain regions 2702 as shown, for example, in FIG. 44. A dielectric material is then deposited into the openings 4402 to form the contact dividers 4404 at the top of the wrap around source/drain contacts 3902. Suitable dielectric materials include, but are not limited to, SiN, SiOx, SiC and/or SiCO, which can be deposited into the openings 4402 using a process such as CVD, ALD or PVD. Following deposition, excess dielectric material can be removed using a process such as CMP.

As with gate divider 3006, only shallow contact dividers 4404 are needed to complete isolation of the adjacent source/drain regions 2702 meaning that the contact dividers 4404 only have to extend down far enough to contact the top of the dielectric bars 502 which, as shown in FIG. 44, is at about a midpoint along the source/drain regions 2702. The dielectric bars 502 in combination with the contact dividers 4404 now separate adjacent wrap around source/drain contacts 3902 in between the source/drain regions 2702.

It is notable that, as described in detail above, regions of the dielectric bars 502 now separating the replacement metal gates 3002 have the first height H1 and the first width W1. See FIG. 43. By comparison, as shown in FIG. 44, the other regions of the dielectric bars 502 now separating the source/drain regions 2702 have the second height H2 and the second width W2, where H1 is greater than H2 (i.e., H1>H2) and W1 is greater than W2 (i.e., W1>W2).

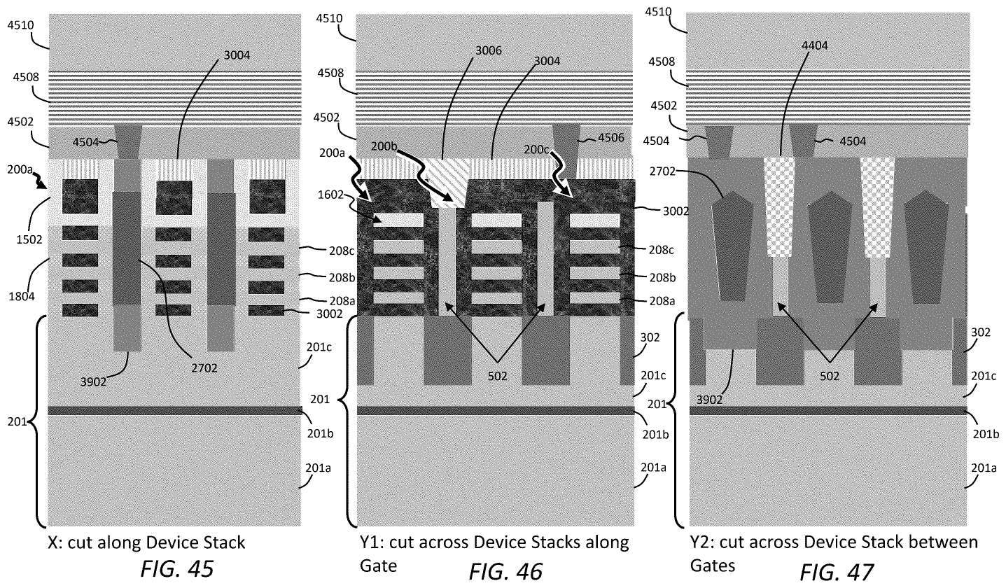

Referring to FIG. 45 (an X cross-sectional view), FIG. 46 (a Y1 cross-sectional view) and FIG. 47 (a Y2 cross-sectional view), middle of line (MOL) source/drain region contacts 4504 and MOL gate contacts 4506 are next formed, followed by back end of line (BEOL) interconnect layer 4508, and bonding to a carrier wafer 4510. Namely, as will be described in detail below, carrier wafer 4510 will enable wafer 201 to be flipped for backside processing.

For instance, an interlayer dielectric 4502 is first deposited onto the dielectric caps 3004 and the wrap around source/drain contacts 3902. For clarity, the terms ‘first’ and ‘second’ may also be used herein when referring to interlayer dielectric 2704 and interlayer dielectric 4502, respectively. Suitable interlayer dielectric 4502 materials include, but are not limited to, SiN, SiOC and/or oxide low-K materials such as SiOx and/or oxide ULK-ILD materials such as pSiCOH, which can be deposited using a process such as CVD, ALD or PVD. Following deposition, the interlayer dielectric 4502 can be planarized using a process such as CMP.

The MOL source/drain region contacts 4504 and MOL gate contacts 4506 are then formed in the interlayer dielectric 4502 over, and in direct contact with, one or more of the wrap around source/drain contacts 3902 and the replacement metal gates 3002, respectively. To form the MOL source/drain region contacts 4504 and MOL gate contacts 4506, standard lithography and etching techniques (see above) are employed to pattern trenches in the interlayer dielectric 4502, which are then filled with a metal or combination of metals. Suitable metals for the MOL source/drain region contacts 4504 and MOL gate contacts 4506 include, but are not limited to, copper (Cu), W, Ru and/or Co, which can be deposited into the trenches using a process such as evaporation, sputtering, ALD, CVD or electrochemical plating. Following deposition, the metal overburden can be removed using a process such as CMP. Prior to depositing the metal(s), an adhesion layer (not shown) can be formed lining the trenches. Suitable adhesion layer materials include, but are not limited to, TiN and/or TaN. Additionally, a seed layer (not shown) can also be deposited into and lining the trenches prior to metal deposition, e.g., to facilitate plating of the metal.

BEOL interconnect layer 4508 generally includes interconnect structures commonly formed in the BEOL during semiconductor device fabrication. Namely, in the BEOL, individual devices such as transistors get interconnected through a series of metal layers. For instance, conductive structures like vias and metal lines can be employed to connect a device to one or more other devices, with the metal lines making lateral connections and the vias making vertical connections amongst different metallization levels. Standard metallization techniques can be employed to form the BEOL interconnect layer 4508. While the individual interconnects present in the BEOL interconnect layer 4508 are not specifically shown in the figures, one skilled in the art would understand how such a BEOL interconnect layer 4508 is implemented for a given semiconductor device application.

Carrier wafer 4510 is then bonded to the frontside of wafer 201 over the BEOL interconnect layer 4508. Suitable carrier wafers include, but are not limited to, silicon, silicon carbide and/or glass wafers. As will be described in detail below, the use of a carrier wafer 4510 will enable wafer 201 to be flipped, thereby permitting any necessary backside processing.

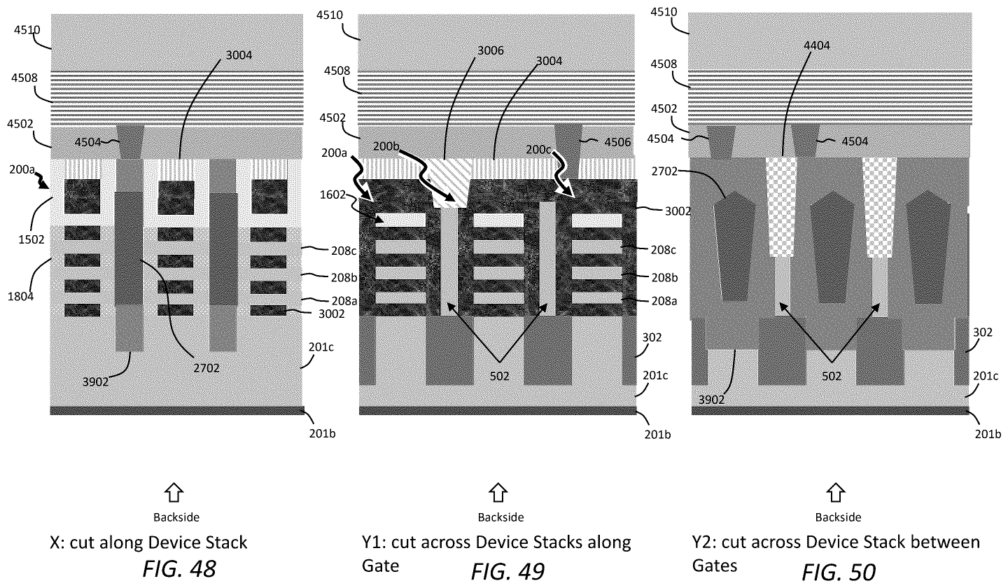

Referring to FIG. 48 (an X cross-sectional view), FIG. 49 (a Y1 cross-sectional view) and FIG. 50 (a Y2 cross-sectional view), an etch is next performed to remove the substrate 201a, stopping on the etch stop layer 201b. It is notable that, prior to removing the substrate 201a, the wafer 201 is first flipped meaning that what was once at the bottom of wafer 201 is now on the top, and vice versa. Doing so, enables top-down processing to be performed on the backside of wafer 201. However, for consistency, the figures themselves have not been flipped in the drawings with the express understanding that processes now being performed on the backside of wafer 201 (see label) would in practice be performed from the top-down on a flipped wafer.

As provided above, etch stop layer 201b can be formed from SiGe or an oxide material, and the substrate 201a can be formed from Si. In that case, an Si-selective etch can be used to remove the substrate 201a.

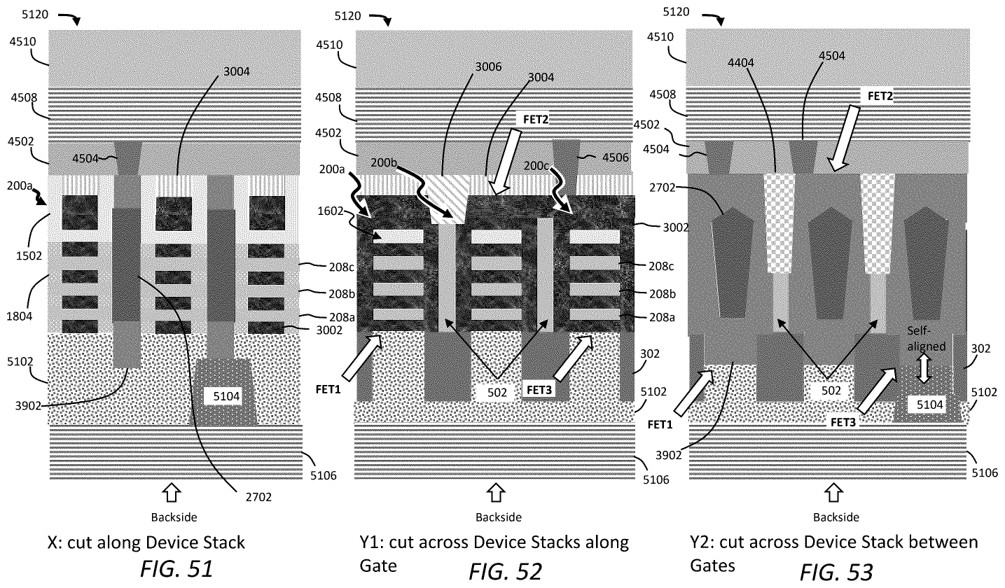

Referring to FIG. 51 (an X cross-sectional view), FIG. 52 (a Y1 cross-sectional view) and FIG. 53 (a Y2 cross-sectional view), the etch stop layer 201b is removed, what remains of the semiconductor layer 201c is removed, a (backside) interlayer dielectric 5102 is formed on the replacement metal gates 3002 and wrap around source/drain contacts 3902, a backside source/drain contact 5104 is formed in the interlayer dielectric 5102 and directly contacting the wrap around source/drain contacts 3902, and a backside power delivery network 5106 is formed on the interlayer dielectric 5102 over the backside source/drain contact 5104.

As provided above, the etch stop layer 201b can be formed from SiGe or an oxide material, and the semiconductor layer 201c can be formed from Si. In that case, a SiGe or oxide-selective etch can be performed to remove the etch stop layer 201b, followed by an Si-selective etch to remove what remains of the semiconductor layer 201c.

For clarity, the term ‘third’ may also be used herein when referring to interlayer dielectric 5102 so as to distinguish it from the ‘first’ interlayer dielectric 2704 and the ‘second’ interlayer dielectric 4502. Suitable interlayer dielectric 5102 materials include, but are not limited to, SiN, SiOC and/or oxide low-K materials such as SiOx and/or oxide ULK-ILD materials such as pSiCOH, which can be deposited using a process such as CVD, ALD or PVD. Following deposition, the interlayer dielectric 5102 can be planarized using a process such as CMP. It is notable, however, that it may be preferable to choose a different material for the interlayer dielectric 5102 than that used for the STI regions 302. Doing so will enable self-alignment of the backside source/drain contact 5104 to a particular one of the wrap around source/drain contacts 3902. For instance, if the STI regions 302 employ an STI oxide, then a nitride material such as SiN may be chosen for the interlayer dielectric 5102. That way, a nitride-selective etch can be employed to form the backside source/drain contact 5104 shown in FIG. 53 that is aligned between two of the STI regions 302 beneath (and in direct contact with) a particular one of the wrap around source/drain contacts 3902.

According to an exemplary embodiment, the backside source/drain contact 5104 is formed from a metal or combination of metals including, but not limited to, Cu, W, Ru and/or Co, which can be deposited using a process such as evaporation, sputtering, ALD, CVD or electrochemical plating. In the same manner described above, an adhesion layer (not shown) and/or a seed layer (not shown) may be employed in the formation of the backside source/drain contact 5104. As provided above, suitable adhesion layer materials include, but are not limited to, TiN and/or TaN.

Backside power delivery network 5106 generally includes backside interconnect structures such as conductive vias and metal lines commonly formed to interconnect various devices, with the metal lines making lateral connections and the vias making vertical connections amongst different metallization levels. Standard metallization techniques can be employed to form the backside power delivery network 5106. While the individual interconnects present in backside power delivery network 5106 are not specifically shown in the figures, given the teachings herein, one skilled in the art would understand how such a backside power delivery network 5106 is implemented for a given semiconductor device application.

As can be seen from FIGS. 51-53, in the resulting semiconductor device 5120, device stacks 200a,b,c, etc. correspond to a first FET (FET1), an second FET (FET2) adjacent to FET1, a third FET (FET3) adjacent to FET2, etc., the replacement metal gates 3002 of which are separated/isolated from one another by dielectric bars 502 and gate divider 3006. The corresponding wrap around source/drain contacts 3902 (fully) surround each of the source/drain regions 2702 of the FET1, FET2, FET3, etc., and are separated/isolated from one another by dielectric bars 502 and contact dividers 4404. Further, in this particular example, the MOL source/drain region contacts 4504 and the MOL gate contacts 4506 connect the wrap around source/drain contacts 3902 and the replacement metal gates 3002, respectively, to the BEOL interconnect layer 4508, while the backside source/drain contact 5104 connects the wrap around source/drain contacts 3902 to the backside power delivery network 5106.

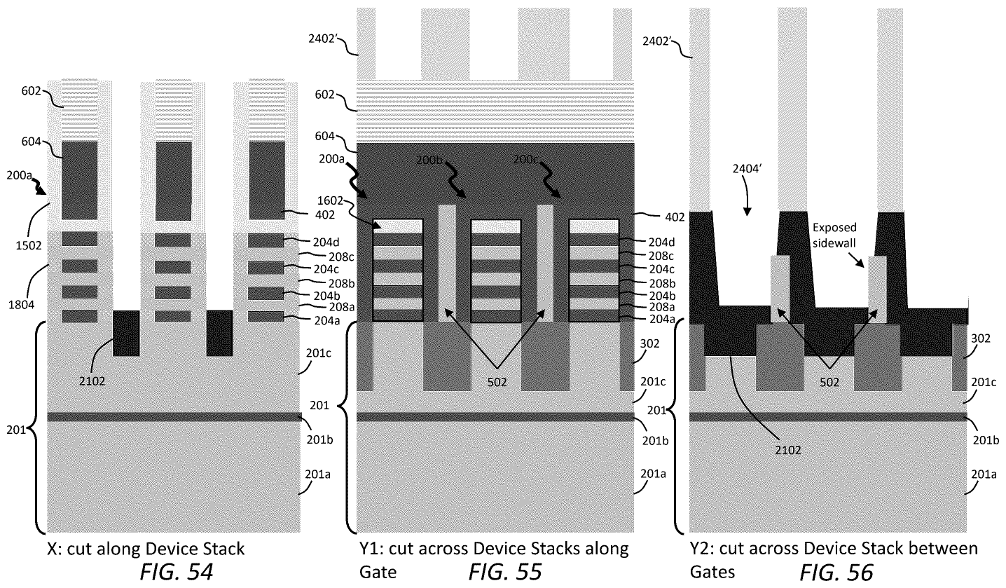

As highlighted above, misalignment tolerances are built in to the present process, while still permitting formation of the present wrap around source/drain contacts. To illustrate this advantage, an alternate embodiment is now described by way of reference to FIGS. 54-59. The process begins in the same manner as described in conjunction with the description of FIGS. 1-23 above and, in that manner, like structures are numbered alike throughout. Specifically, what is provided in FIG. 54, FIG. 55 and FIG. 56 follows from the structures depicted in FIG. 21, FIG. 22 and FIG. 23, respectively.

Referring to FIG. 54 (an X cross-sectional view), FIG. 55 (a Y1 cross-sectional view) and FIG. 56 (a Y2 cross-sectional view), source/drain cavities 2404′ are patterned in the sacrificial placeholder 2102. Namely, in the same manner as above, standard lithography and etching techniques are used to pattern a block mask 2402′ (e.g., an organic planarizing layer) with the footprint and location of each of the source/drain cavities 2404′. A directional (anisotropic) etching processes such as RIE can then be employed to transfer the pattern to the sacrificial placeholder 2102 to form the source/drain cavities 2404′ therein. Following formation of the source/drain cavities 2404′, the block mask 2402′ can be removed (e.g., by ashing).

By comparison with the previous example, here the source/drain cavities 2404′ formed are slightly misaligned with the dielectric bars 502. Namely, referring to FIG. 56, the source/drain cavities 2404′ actually expose sidewall portions of the adjacent dielectric bars 502 in the source/drain area (i.e., area in which the source/drain regions of the semiconductor device will be formed (see below)). This can be compared with the previous example shown in FIG. 26 where the sacrificial placeholder 2102 remains covering the dielectric bars 502 post-etching of the source/drain cavities 2404. However, even with this misalignment, the present wrap around source/drain contacts can still be formed in the same manner as described above.

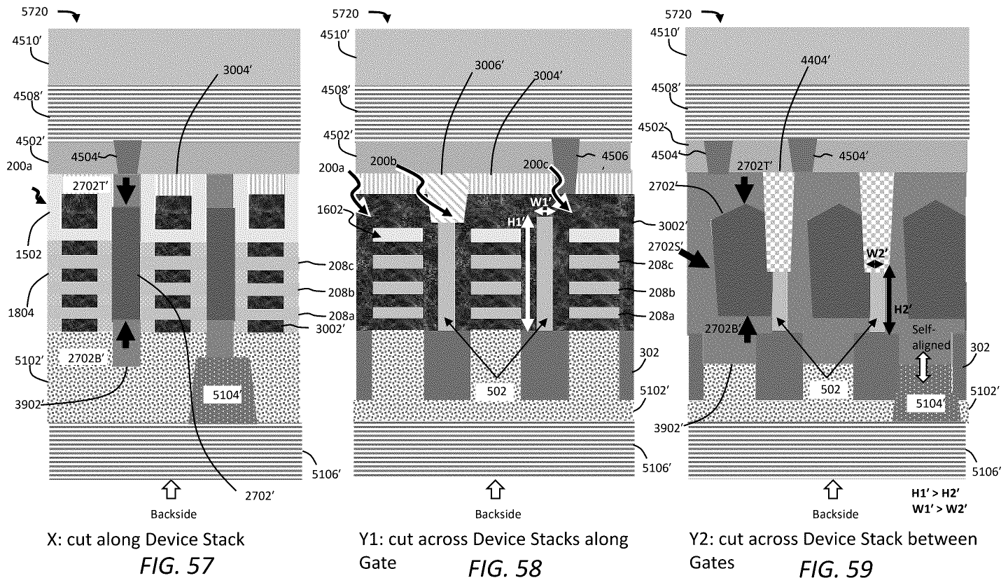

The intermediate steps, which are performed in precisely the same manner as in the previous example, are omitted for ease and clarity of description. However, referring to FIG. 57 (an X cross-sectional view), FIG. 58 (a Y1 cross-sectional view) and FIG. 59 (a Y2 cross-sectional view), it is recalled from above that source/drain regions 2702′ are formed on opposite sides of the active layers 208a,b,c, etc., replacement metal gates 3002′ are formed surrounding a portion of each of the active layers 208a,b,c, etc. in a GAA configuration, dielectric caps 3004′ are formed over the replacement metal gates 3002′, a gate divider 3006′ is formed at a top of the replacement metal gates 3002′, wrap around source/drain contacts 3902′ are formed that surround each of the (epitaxial) source/drain regions 2702′, contact dividers 4404′ are formed at a top of the wrap around source/drain contacts 3902′, MOL source/drain region contacts 4504′ and MOL gate contacts 4506′ are formed in an interlayer dielectric 4502′, followed by a BEOL interconnect layer 4508′, and bonding to a carrier wafer 4510′, the substrate 201a, the etch stop layer 201b and the semiconductor layer 201c are removed, and a (backside) interlayer dielectric 5102′ is formed on the replacement metal gates 3002′ and wrap around source/drain contacts 3902′, a backside source/drain contact 5104′ is formed in the interlayer dielectric 5102′ and directly contacting the wrap around source/drain contacts 3902′, and a backside power delivery network 5106′ is formed on the interlayer dielectric 5102′ over the backside source/drain contact 5104′.

Notably, as shown particularly in FIG. 57 and FIG. 59, in the resulting semiconductor device 5720, the wrap around source/drain contacts 3902′ partially surround each of the (epitaxial) source/drain regions 2702′. More specifically, in this particular alternate example, wrap around source/drain contacts 3902′ directly contact a bottom 2702B′, a top 2702T′, and a sidewall 2702S′ of each of the source/drain regions 2702′. Due to the misalignment during formation of the source/drain cavities 2404′, the other opposing sidewall of the source/drain regions 2702′ abuts the dielectric bars 502/contact dividers 4404′. Notwithstanding, wrap around source/drain contacts 3902′ still surround multiple sides (i.e., bottom, top and sidewall) of each of the source/drain regions 2702′. For comparison, in the previous example, the wrap around source/drain contacts 3902 fully surrounded each of the (epitaxial) source/drain regions 2702 by directly contacting a bottom 2702B, a top 2702T, and opposing sidewalls 2702S of each of the source/drain regions 2702. Sec, e.g., FIG. 39 and FIG. 41.

It is further notable that, as above, regions of the dielectric bars 502 now separating the replacement metal gates 3002′ have a first height H1′ and a first width W1′. See FIG. 58. By comparison, as shown in FIG. 59, the other regions of the dielectric bars 502 now separating the source/drain regions 2702′ have a second height H2′ and the second width W2′, where H1′ is greater than H2′ (i.e., H1′>H2′) and W1′ is greater than W2′ (i.e., W1′>W2′).

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor device, comprising:
at least a first field-effect transistor (FET1) and a second FET (FET2), adjacent to one another on a wafer;
a dielectric bar between gates of the FET1 and the FET2, and between source/drain regions of the FET1 and the FET2; and
wrap around source/drain contacts that at least partially surround the source/drain regions of the FET1 and the FET2.

2. The semiconductor device of claim 1, wherein a portion of the dielectric bar between the gates of the FET1 and the FET2 has a height H1, wherein another portion of the dielectric bar between the source/drain regions of the FET1 and the FET2 has a height H2, and wherein H1>H2.

3. The semiconductor device of claim 1, wherein a portion of the dielectric bar between the gates of the FET1 and the FET2 has a width W1, wherein another portion of the dielectric bar between the source/drain regions of the FET1 and the FET2 has a width W2, and wherein W1>W2.

4. The semiconductor device of claim 1, wherein the wrap around source/drain contacts directly contact a bottom, a top, and at least one sidewall of the source/drain regions of the FET1 and the FET2.

5. The semiconductor device of claim 1, wherein the wrap around source/drain contacts fully surround the source/drain regions of the FET1 and the FET2.

6. The semiconductor device of claim 5, wherein the wrap around source/drain contacts directly contact a bottom, a top, and opposing sidewalls of the source/drain regions of the FET1 and the FET2.

7. The semiconductor device of claim 1, further comprising:
a contact divider in contact with the dielectric bar, wherein the contact divider and the dielectric bar separate adjacent ones of the wrap around source/drain contacts between the source/drain regions of the FET1 and the FET2.

8. The semiconductor device of claim 1, further comprising:
a backside power delivery network; and
a backside source/drain contact that connects one of the wrap around source/drain contacts to the backside power delivery network.

9. A semiconductor device, comprising:
at least a first field-effect transistor (FET1) and a second FET (FET2), adjacent to one another on a wafer;
a shallow trench isolation (STI) region between the FET1 and the FET2;
a dielectric bar between gates of the FET1 and the FET2, and between source/drain regions of the FET1 and the FET2, wherein the dielectric bar is centered over, and directly contacts the STI region, wherein a portion of the dielectric bar between the gates of the FET1 and the FET2 has a height H1, wherein another portion of the dielectric bar between the source/drain regions of the FET1 and the FET2 has a height H2, and wherein H1>H2; and
wrap around source/drain contacts that at least partially surround the source/drain regions of the FET1 and the FET2.

10. The semiconductor device of claim 9, wherein the portion of the dielectric bar between the gates of the FET1 and the FET2 has a width W1, wherein the another portion of the dielectric bar between the source/drain regions of the FET1 and the FET2 has a width W2, and wherein W1>W2.

11. The semiconductor device of claim 9, wherein the wrap around source/drain contacts directly contact a bottom, a top, and at least one sidewall of the source/drain regions of the FET1 and the FET2.

12. The semiconductor device of claim 9, wherein the wrap around source/drain contacts fully surround the source/drain regions of the FET1 and the FET2.

13. The semiconductor device of claim 12, wherein the wrap around source/drain contacts directly contact a bottom, a top, and opposing sidewalls of the source/drain regions of the FET1 and the FET2.

14. The semiconductor device of claim 9, further comprising:
a contact divider in contact with the dielectric bar, wherein the contact divider and the dielectric bar separate adjacent ones of the wrap around source/drain contacts between the source/drain regions of the FET1 and the FET2.

15. The semiconductor device of claim 9, further comprising:
a backside power delivery network; and
a backside source/drain contact that connects one of the wrap around source/drain contacts to the backside power delivery network.

16. A method of fabricating a semiconductor device, the method comprising:
forming at least a first device stack corresponding to a first field-effect transistor (FET1) and a second device stack corresponding to a second FET (FET2), adjacent to one another on a wafer, wherein the first device stack and the second device stack each comprises sacrificial layers and active layers;
forming a dielectric bar between the first device stack and the second device stack;
depositing a sacrificial placeholder in a source/drain area adjacent to the first device stack and the second device stack;
forming source/drain regions of the FET1 and the FET2 in the sacrificial placeholder;
removing the sacrificial layers from the first device stack and the second device stack;
forming gates of the FET1 and the FET2 that surround a portion of each of the active layers in a gate-all-around configuration; and
replacing the sacrificial placeholder with wrap around source/drain contacts that at least partially surround the source/drain regions of the FET1 and the FET2, wherein the dielectric bar is present between the gates of the FET1 and the FET2, and between the source/drain regions of the FET1 and the FET2.

17. The method of claim 16, further comprising:
forming sacrificial spacers along a top and sidewalls of the first device stack and the second device stack;
forming the dielectric bar in a space between the sacrificial spacers; and
removing the sacrificial spacers along with the sacrificial layers prior to forming the gates of the FET1 and the FET2.

18. The method of claim 16, wherein a portion of the dielectric bar between the gates of the FET1 and the FET2 has a height H1, wherein another portion of the dielectric bar between the source/drain regions of the FET1 and the FET2 has a height H2, and wherein H1>H2.

19. The method of claim 16, wherein a portion of the dielectric bar between the gates of the FET1 and the FET2 has a width W1, wherein another portion of the dielectric bar between the source/drain regions of the FET1 and the FET2 has a width W2, and wherein W1>W2.

20. The method of claim 16, wherein the wrap around source/drain contacts directly contact a bottom, a top, and at least one sidewall of the source/drain regions of the FET1 and the FET2.
